(19) United States
(12) Patent Application Publication
(10) Pub. No.: US 2024/0213386 A1
(43) Pub. Date: Jun. 27, 2024

(54) Encapsulant Sheet with Low Potential Induced Degradation

(71) Applicant: Dow Global Technologies LLC, Midland, MI (US)

(72) Inventors: Wenxin Zhang, Shanghai (CN); Yabin Sun, Shanghai (CN); Yunfeng Yang, Shanghai (CN); Yuyan Li, Shanghai (CN)

(21) Appl. No.: 18/254,591

(22) PCT Filed: Dec. 17, 2020
(86) PCT No.: PCT/CN2020/137367

§ 371 Date: May 25, 2023

(51) Int. Cl. H01L 31/048; H01L 31/18

(52) U.S. Cl. CPC H01L 31/0481; H01L 31/186

(57) ABSTRACT

An encapsulant sheet includes a material formed from an ethylene/C₄-C₈α-olefin copolymer having a resin volume resistivity (VR) from greater than 1×10¹⁴Ω cm at 60° C. to less than 1×10¹⁶Ω cm at 60° C. and from 0.01 wt % to 0.2 wt % of an ion scavenger. The encapsulant sheet has a transmittance greater than 91%. A photovoltaic module (10) includes a front encapsulant sheet (12a) and a rear encapsulant sheet (12b) composed of the material. The photovoltaic module (10) has a power loss after potential induced degradation (PID) test from 0.05% to less than 5%.

### BACKGROUND

A challenge in the maintenance of long-term, reliable, and stable operation of a crystalline silicon solar photovoltaic module (PV module) is the reduction of the phenomenon of potential induced degradation (or “PID”). In the presence of the electric field generated by the PV module, sodium ions (Na⁺) from the glass cover sheet migrate through the encapsulant sheet (made of polymeric material), degrading the encapsulant material and contributing to the PID phenomenon. PID can reduce the output power of a solar PV module by 20%, and in severe cases PID can reduce the output power of a solar PV module by more than 50%.

The demand for bifacial PV modules (such as high efficiency PERC bifacial PV modules) has grown dramatically in recent years. Bifacial PV modules exhibit unacceptably high PID when using incumbent ethylene vinyl acetate EVA as the material for the encapsulant sheet because ion migration occurs through both the glass front cover sheet and the rear glass cover sheet. Conventional polyolefin elastomer also has not demonstrated the ability to withstand PID when used as the encapsulant sheet material in bifacial PV modules.

The art recognizes the need for a polymeric material for encapsulant sheet in a PV module that can resist PID, and in particular, a polymeric material resistant to PID in bifacial PV module.

### SUMMARY

The present disclosure is directed to an encapsulant sheet. In an embodiment, the encapsulant sheet includes a material formed from an ethylene/C₄-C₈ α-olefin copolymer having a resin volume resistivity (VR) from greater than 1×10¹⁴Ω cm at 60° C. to less than 1×10¹⁶Ω cm at 60° C. and from 0.01 wt % to 0.2 wt % of an ion scavenger. The encapsulant sheet has a transmittance greater than 91%.

The present disclosure is also directed to a photovoltaic module. In an embodiment, the photovoltaic module includes (A) a front cover sheet, (B) a front encapsulant sheet, (C) a photovoltaic cell, (D) a rear encapsulant sheet, and (E) a rear cover sheet. The front encapsulant sheet (B) is composed of (i) an ethylene/C₄-C₈ α-olefin copolymer having a resin volume resistivity (VR) from greater than 1×10¹⁴Ω cm at 60° C. to less than 1×10¹⁶Ω cm at 60° C., and (ii) from 0.01 wt % to 0.2 wt % of an ion scavenger. The rear encapsulant sheet (D) is composed of (i) an ethylene/C₄-C₈ α-olefin copolymer having a resin volume resistivity (VR) from greater than 1×10¹⁴Ω cm at 60° C. to less than 1×10¹⁶Ω cm at 60° C., and (ii) from 0.01 wt % to 0.2 wt % of an ion scavenger. The photovoltaic module has a power loss after potential induced degradation (PID) test from 0.05% to less than 5%.

### BRIEF DESCRIPTION OF THE DRAWING

FIG. 1 is an exploded perspective view of an exemplary photovoltaic module.

### DEFINITIONS

Any reference to the Periodic Table of Elements is that as published by CRC Press, Inc., 1990-1991. Reference to a group of elements in this table is by the new notation for numbering groups.

For purposes of United States patent practice, the contents of any referenced patent, patent application or publication are incorporated by reference in their entirety (or its equivalent US version is so incorporated by reference) especially with respect to the disclosure of definitions (to the extent not inconsistent with any definitions specifically provided in this disclosure) and general knowledge in the art.

The numerical ranges disclosed herein include all values from, and including, the lower and upper value. For ranges containing explicit values (e.g., 1, or 2, or 3 to 5, or 6, or 7), any subrange between any two explicit values is included (e.g., 1 to 2; 2 to 6; 5 to 7; 3 to 7; 5 to 6; etc.).

Unless stated to the contrary, implicit from the context, or customary in the art, all parts and percents are based on weight and all test methods are current as of the filing date of this disclosure.

“Alpha-olefin” or “α-olefin,” as used herein, is a hydrocarbon molecule having an ethylenic unsaturation at the primary (alpha) position. For example, “(C₃-C₂₀)alpha-olefins,” as used herein, are hydrocarbon molecules composed of hydrocarbon molecules comprising (i) only one ethylenic unsaturation, this unsaturation located between the first and second carbon atoms, and (ii) at least 3 carbon atoms, or of 3 to 20 carbon atoms. For example, (C₃-C₂₀) alpha-olefin, as used herein, refers to H₂C═C(H)—R, wherein R is a straight chain (C₁-C₁₈)alkyl group. (C₁-C₁₈)alkyl group is a monovalent unsubstituted saturated hydrocarbon having from 1 to 18 carbon atoms.

“Blend”, “polymer blend” and like terms mean a composition of two or more polymers. Such a blend may or may not be miscible. Such a blend may or may not be phase separated. Such a blend may or may not contain one or more domain configurations, as determined from transmission electron spectroscopy, light scattering, x-ray scattering, and any other method used to measure and/or identify domain configurations. Blends are not laminates, but one or more layers of a laminate may contain a blend.

The term “coagent” means a compound that enhances crosslinking, i.e., a curing coagent.

“Composition,” as used herein, includes a mixture of materials which comprise the composition, as well as reaction products and decomposition products formed from the materials of the composition.

The terms “comprising,” “including,” “having,” and their derivatives, are not intended to exclude the presence of any additional component, step or procedure, whether or not the same is specifically disclosed. In order to avoid any doubt, all compositions claimed through use of the term “comprising” may include any additional additive, adjuvant, or compound, whether polymeric or otherwise, unless stated to the contrary. In contrast, the term, “consisting essentially of” excludes from the scope of any succeeding recitation any other component, step or procedure, excepting those that are not essential to operability. The term “consisting of” excludes any component, step or procedure not specifically listed. The term “or,” unless stated otherwise, refers to the listed members individual as well as in any combination.

The terms “curing” and “crosslinking” are used interchangeably herein to mean forming a crosslinked product (network polymer). “Directly contacts” refers to a layer configuration whereby a first layer is located immediately adjacent to a second layer and no intervening layers or no intervening structures are present between the first layer and the second layer.

“Elastomer” and like terms refer to a rubber-like polymer that can be stretched to at least twice its original length and which retracts very rapidly to approximately its original length when the force exerting the stretching is released. An elastomer has an elastic modulus of about 10,000 psi (68.95 MPa) or less and an elongation usually greater than 200% in the uncrosslinked state at room temperature using the method of ASTM D638-72.

An “ethylene-based polymer,” as used herein is a polymer that contains more than 50 weight percent polymerized ethylene monomer (based on the total amount of polymerizable monomers) and, optionally, may contain at least one comonomer.

“Polymer,” as used herein, refers to a polymeric compound prepared by polymerizing monomers, whether of the same or a different type. The generic term polymer thus embraces the term homopolymer (employed to refer to polymers prepared from only one type of monomer, with the understanding that trace amounts of impurities can be incorporated into the polymer structure), and the term interpolymer as defined herein. Trace amounts of impurities, for example, catalyst residues, may be incorporated into and/or within the polymer.

### Test Methods

Density is measured in accordance with ASTM D792, Method B. Results are reported in grams per cubic centimeter (g/cc).

Differential Scanning Calorimetry (DSC). Differential Scanning Calorimetry (DSC) can be used to measure the melting, crystallization, and glass transition behavior of a polymer over a wide range of temperature. For example, the TA Instruments Q2000 DSC, equipped with an RCS (refrigerated cooling system) and an autosampler is used to perform this analysis. During testing, a nitrogen purge gas flow of 50 ml/min is used. Each sample is melt pressed into a thin film at about 175° C.; the melted sample is then air-cooled to room temperature (about 25° C.). A 3-10 mg, 6 mm diameter specimen is extracted from the cooled polymer, weighed, placed in a light aluminum pan (ca 50 mg), and crimped shut. Analysis is then performed to determine its thermal properties.

The thermal behavior of the sample is determined by ramping the sample temperature up and down to create a heat flow versus temperature profile. First, the sample is rapidly heated to 180° C. and held isothermal for 3 minutes in order to remove its thermal history. Next, the sample is cooled to -80° C. at a 10° C./minute cooling rate and held isothermal at -80° C. for 3 minutes. The sample is then heated to 180ºC (this is the “second heat” ramp) at a 10° C./minute heating rate. The cooling and second heating curves are recorded. The cool curve is analyzed by setting baseline endpoints from the beginning of crystallization to −20° C. The heat curve is analyzed by setting baseline endpoints from −20° C. to the end of melt. The values determined are extrapolated onset of melting, Tm, and extrapolated onset of crystallization, Tc. Heat of fusion (Hf) (in Joules per gram), and the calculated % crystallinity for polyethylene samples using the following Equation: % Crystallinity=((H_{f})/292 J/g)×100.

The heat of fusion (Hf) (also known as melt enthalpy) and the peak melting temperature are reported from the second heat curve.

Melting point, Tm, is determined from the DSC heating curve by first drawing the baseline between the start and end of the melting transition. A tangent line is then drawn to the data on the low temperature side of the melting peak. Where this line intersects the baseline is the extrapolated onset of melting (Tm). This is as described in Bernhard Wunderlich, The Basis of Thermal Analysis, in Thermal Characterization of Polymeric Materials 92, 277-278 (Edith A. Turi ed., 2d ed. 1997).

Melt Index. The term “melt index,” or “MI” as used herein, refers to the measure of how easily a thermoplastic polymer flows when in a melted state. Melt index, or I₂,is measured in accordance by ASTM D 1238, Condition 190° C/2.16 kg, and is reported in grams eluted per 10 minutes (g/10 min). The I10 is measured in accordance with ASTM D 1238, Condition 190° C./10 kg, and is reported in grams eluted per 10 minutes (g/10 min).

PID Test. Potential induced degradation (PID) test at module level was conducted in accordance with the procedures described in IEC 62804-1. (1) The initial power output of module samples was recorded with a pulsed solar simulator (Burger PS8/PSS8) with procedures described in IEC 60904. (2) PID stress process was performed in an environmental chamber under 85° C/85%RH condition. Module samples were connected with a power supply to generate a typical negative bias voltage of 1500V. A standard test takes 96 hours (h). (3) After stress process, all module samples were retested for power output. The results are compared to the initial measurements to further calculate the power loss. The IEC standard for power loss after PID test for 96 h is less than 5% for both front and rear side of PV module.

Transmittance. The mean transmittance of the sample sheets was determined using a LAMBDA 950 UV/Vis Spectrophotometer (PerkinElmer) equipped with a 150 mm integrating sphere. At least three samples were tested and the average transmittance from 380 nm to 1100 nm is collected.

Vicat softening point was determined in accordance with ASTM D1525.

Volume Resistivity (VR) Test. The volume resistivity is tested according to the following, which is based on ASTM D257. The measurement is made using a Keithley 6517 B electrometer, combined with the Keithley 8009 test fixture. The Keithley model 8009 test chamber is located inside the forced air oven and is capable of operating at elevated temperatures (the maximum temperature of the oven is 80° C.). The leakage current is directly read from the instrument and the following equation is used to calculate the volume resistivity:

ρ=V×AI×tρ=V×AI×t

where ρ is the volume resistivity (ohm-cm), V is applied voltage (volts), A is electrode contact area (cm²), I is the leakage current (amps) and t is the average thickness of the sample. To get the average thickness of the samples, the thickness of each sample was measured before the tests, with five points of the sample measured to get an average thickness. The volume resistivity test was conducted at 1000 volts at room temperature (23° C.) and at 60° C. Two compression molded encapsulant sheets are tested to get the average.

For the resin VR test (or “resin VR”), the resin is compression molded into a sample sheet (˜500 nm) and the foregoing VR test is performed on the sample sheet. For the sheet VR test (or “sheet VR”), extruded sample sheets were cured (cross-linked) by a lamination process. The lamination process was conducted on a PENERGY L036 laminator at 150° C. for 20 minutes, including 4 minutes vacuum process and 16 minutes pressing. The sample sheets were placed in between two PTFE sheets during the lamination process. After lamination, the PTFE sheets were removed. The foregoing VR test was then performed on the cured sample sheets.

### DETAILED DESCRIPTION

The present disclosure provides an encapsulant sheet. In an embodiment, the encapsulant sheet includes a material formed from an ethylene/C₄-C₈ α-olefin copolymer having a resin volume resistivity (VR) from greater than 1×10¹⁴Ω cm at 60° C. to less than 1×10¹⁶Ω cm at 60° C. The encapsulant sheet includes from 0.01 wt % to 0.2 wt % of an ion scavenger. The encapsulant sheet has a transmittance greater than 91%.

### 1. Ethylene/C₄-C₈ α-Olefin Copolymer

The encapsulant sheet includes an ethylene/C₄-C₈ α-olefin copolymer. The ethylene/C₄-C₈ α-olefin copolymer consists of (i) polymerized units of ethylene and (ii) polymerized units of a C₄-C₈ α-olefin comonomer. Nonlimiting examples of suitable ethylene/C₄-C₈ α-olefin copolymer include ethylene/butene copolymer, ethylene/hexene copolymer, and ethylene/octene copolymer. In an embodiment the ethylene/C₄-C₈ α-olefin copolymer is void of, or otherwise excludes, vinyl acetate.

The ethylene/C₄-C₈ α-olefin copolymer has a resin volume resistivity (VR) from greater than 1×10¹⁴ Ω cm at 60° C. to less than 1×10¹⁶ Ω cm at 60° C., or a VR greater than 1×10¹⁴ Ω cm at 60° C. to 1×10¹⁵Ω cm at 60° C.

In an embodiment, the ethylene/C₄-C₈ α-olefin copolymer resin is an ethylene/octene copolymer having one, some, or all of the following properties:
(i) a resin VR from greater than 1×10¹⁴Ω at 60° C. to less than 1×10¹⁶Ω cm at 60° C., or a resin VR from greater than 1×10¹⁴Ω cm at 60° C. to 1×10¹⁵Ω cm at 60° C.; and/or
(ii) a sheet VR from greater than 1×10¹⁴Ω cm at 23° C. to less than 1×10¹⁶Ω cm at 23° C.; and/or
(iii) a density from 0.860 g/cc to 0.890 g/cc, or from 0.860 g/cc to 0.880 g/cc, or from 0.865 g/cc to 0.875 g/cc; and/or
(iv) a melt index (12) from 10 g/10 min to 20 g/10 min, or from 10 g/10 min to 15 g/10 min, or from 11 g/10 min to 14 g/10 min ; and/or
(v) a melting temperature, Tm, from 50° C. to 90° C., or from 50° C. to 80° C., or 55° C. to 75° C., or from 60° C. to 70° C.; and/or
(vi) a Vicat softening temperature from 30° C. to 50° C., or from 35° C. to 39 ° C.

The encapsulant sheet includes an ion scavenger. The ion scavenger traps conductive materials (ions, radicals, Na+ions, and the like) that lower the insulating property and lower PID resistance. The ion scavenger contributes to the PID resistance of the encapsulant sheet. The encapsulant sheet includes from 0.01 wt % to 0.2 wt %, or from 0.02 wt % to 0.2 wt %, or from 0.02 wt % to 0.1 wt %, or from 0.03 wt % to less than 0.1 wt % of the ion scavenger. Weight percent is based on total weight of the encapsulant sheet. Nonlimiting examples of suitable ion scavenger include metal phosphate such as zirconium phosphate, bismuth phosphate, titanium phosphate, tin phosphate, tantalum phosphate, and combinations thereof.

In an embodiment, the ion scavenger is a zirconium phosphate. In a further embodiment, the ion scavenger is Zr₁₋ₓHfₓHₐ(PO₄)_{b}mH₂O wherein
0≤×≤0.2,
2<b≤2.1,
a is 3,
b-a=4, and
0≤m ≤2.

In an embodiment, the material to form the encapsulant sheet includes a cure package. The cure package includes an organic peroxide, an optional curing agent, and optional silane coupling agent. When the cure package is present, the material is a curable composition to form a crosslinked encapsulant sheet.

When the coupling package is present, the material to form the encapsulant sheet includes the organic peroxide in an amount from 0.1 wt % to 3 wt %, or from 0.1 wt % to 2.5 wt %, or from 0.1 wt % to 2 wt %, or from 0.5 wt % to 1.5 wt %, or from 1 wt % to 1.5 wt %, based on the total weight of the material. Weight percent is based on total weight of the material to form the encapsulant sheet. The organic peroxide is a molecule containing carbon atoms, hydrogen atoms, and two or more oxygen atoms, and having at least one —O—O— group, with the proviso that when there is more than one —O—O— group, each —O—O— group is bonded indirectly to another —O—O— group via one or more carbon atoms, or collection of such molecules. Nonlimiting examples of organic peroxides include peroxycarbonates, diacylperoxides, peroxyketal, dialkyl peoxide, peroxyesters, and combinations thereof.

In an embodiment, the organic peroxide is a dialkylperoxide, monoperoxide of formula R^{O}—O—O—R^{O}, wherein each R^{O} independently is a (C₁-C₂₀)alkyl group or (C₆-C₂₀)aryl group. Each (C₁-C₂₀)alkyl group independently is unsubstituted or substituted with 1 or 2 (C₆-C₁₂)aryl groups. Each (C₆-C₂₀)aryl group is unsubstituted or substituted with 1 to 4 (C₁-C₁₀)alkyl groups. Alternatively, the organic peroxide may be a diperoxide of formula R^{O}—O—O—R—O—O—R^{O}, wherein R is a divalent hydrocarbon group such as a (C₂-C₁₀)alkylene, (C₃-C₁₀)cycloalkylene, or phenylene, and each R^{O} is as defined above.

Non-limiting examples of suitable organic peroxides include tert-butylperoxy-2-ethylhexyl carbonate (TBEC); tert-amylperoxy-2-ethylhexyl carbonate (TAEC), 1,1-Di(tert-butylperoxy)-3,3,5-trimethylcyclohexane, 1,1-Di(tert-butylperoxy)cyclohexane, 3,6,9-Triethyl-3,6,9-trimethyl-1,4,7-triperoxonane, tertio-butyl peroxy-2-ethylhexanoate dicumyl peroxide; lauryl peroxide; benzoyl peroxide; tertiary butyl perbenzoate; di(tertiary-butyl) peroxide; cumene hydroperoxide; 2,5-dimethyl-2,5-di(t-butyl-peroxy)hexyne-3; 2,-5-di-methyl-2,5-di(t-butyl-peroxy)hexane; tertiary butyl hydroperoxide; isopropyl percarbonate; alpha, alpha'-bis(tertiary-butylperoxy)diisopropylbenzene; t-butylperoxy-2-ethylhexyl-monocarbonate; 1,1-bis(t-butylperoxy)-3,5,5-trimethyl cyclohexane; 2,5-dimethyl-2,5-dihydroxyperoxide; t-butylcumylperoxide; alpha, alpha'-bis(t-butylperoxy)-p-diisopropyl benzene; bis(1,1-dimethylethyl) peroxide; bis(1,1-dimethylpropyl) peroxide; 2,5-dimethyl-2,5-bis(1,1-dimethylethylperoxy) hexane; 2,5-dimethyl-2,5-bis(1,1-dimethylethylperoxy) hexyne; 4,4-bis(1,1-dimethylethylperoxy) valeric acid; butyl ester; 1,1-bis(1,1-dimethylethylperoxy)-3,3,5-trimethylcyclohexane; benzoyl peroxide; tert-butyl peroxybenzoate; di-tert-amyl peroxide (“DTAP”); bis(alpha-t-butyl-peroxyisopropyl) benzene (“BIPB”); isopropylcumyl t-butyl peroxide; t-butylcumylperoxide; di-butyl peroxide; 2,5-bis(tbutylperoxy)-2,5-dimethylhexane; 2,5-bis(t-butylperoxy)-2,5-dimethylhexyne-3,1,1-bis(tbutylperoxy)- 3,3,5-trimethylcyclohexane; isopropylcumyl cumylperoxide; butyl 4,4-di(tertbutylperoxy) valerate; di(isopropylcumyl) peroxide; and combinations thereof.

When the coagent is present in the cure package, the material to form the encapsulant sheet includes the coagent in an amount from 0.1 wt % to 2.5 wt %, or 0.1 wt % to 2 wt %, or from 0.5 wt % to 1.5 wt %, or from 0.5 wt % to 1.0 wt %, based on the total weight of the material used to form the encapsulant sheet. A nonlimiting example of a suitable coagent is triallyl isocyanurate.

When the silane coupling agent is present in the cure package, the material to form the encapsulant sheet includes from 0.01 wt % to 2 wt %, or from 0.05 wt % to 1.5 wt %, or from 0.1 wt % to 1 wt %, from 0.15 wt % to 0.5 wt %, from 0.2 wt % to 0.4 wt %, or from 0.25 wt % to 0.3 wt % of the silane coupling agent, based on total weight of the material used to form the encapsulant sheet. Nonlimiting examples of suitable silane coupling agent include y-chloropropyl trimethoxysilane, vinyl trimethoxysilane, vinyl triethoxysilane, vinyl-tris-(β-methoxy)silane, allyltrimethoxysilane, y-methacryloxypropyl trimethoxysilane, β-(3,4-ethoxy-cyclohexyl)ethyl trimethoxysilane, γ-glycidoxypropyl trimethoxysilane, γ-mercaptopropyltrimethoxysilane, γ-aminopropyl trimethoxysilane, N-β-(aminoethyl)-γ-aminopropyl trimethoxysilane, 3-(trimethoxysilyl)propylmethacrylate, and combinations thereof.

In an embodiment, the silane coupling agent is selected from vinyl trimethoxysilane, or 3-(trimethoxysilyl)propylmethacrylate, or allyltrimethoxysilane.

The material to form the encapsulant sheet may include one or more optional additives. When the optional additive(s) is/are present, the additives are present in an amount of from greater than zero, or 0.01 wt %, or 0.1 wt % to 1 wt %, or 2 wt %, or 3 wt %, or 5 wt % based on the total weight of the material. Non-limiting examples of suitable additives include antioxidant, anti-blocking agent, stabilizing agent, colorant, ultra-violet (UV) absorber or stabilizer, flame retardant, compatibilizer, filler, hindered amine stabilizer, tree retardant, methyl radical scavenger, scorch retardant, nucleating agent, processing aids, and combinations thereof.

In an embodiment, the material to form the encapsulant sheet includes (i) the ethylene/C₄-C₈ α-olefin copolymer having a resin volume resistivity (VR) from greater than 1×10¹⁴Ω cm at 60° C. to less than 1×10¹⁶Ω cm at 60° C., (ii) from 0.01 wt % to 0.2 wt % of the ion scavenger, and a cure package containing (iii) the organic peroxide, (iv) the coagent, (v) the silane coupling agent, and (vi) a UV stabilizer. The ion scavenger is compounded into the ethylene/C₄-C₈ α-olefin copolymer pellets. The compounded ethylene/C₄-C₈ α-olefin copolymer pellets are subsequently mixed with the curing package of the peroxide, the coagent, and the silane-coupling agent (and optional additives). The pellets of the ethylene/C₄-C₈ α-olefin copolymer (with ion scavenger) are soaked in the curing package composed of the organic peroxide, the coagent and the silane coupling agent, and the soaked pellets are then further processed (e.g., compounded, extruded, molded, etc.) to form the encapsulant sheet composed of crosslinked ethylene/C₄-C₈ α-olefin copolymer, ion scavenger, and optional additives.

The crosslinked encapsulant sheet is structurally and physically distinct compared to the material that is cured to produce the crosslinked encapsulant sheet. In an embodiment, the encapsulant sheet is a crosslinked sheet and is composed of from 99.8 wt % to 99.98 wt % of an ethylene/C₄-C₈ α-olefin copolymer and from 0.02 wt % to 0.2 wt % of an ion scavenger that is a zirconium phosphate. The encapsulant sheet has a VR (sheet VR) from greater than 1×10¹⁴Ω cm at 23° C. to less than 1×10¹⁶Ω cm at 23° C., or a sheet VR from greater than 1×10¹⁴Ω cm at 23° C. to less than 7.0×10¹⁵Ω cm at 23° C. The ethylene/C₄-C₈ α-olefin copolymer is an ethylene/octene copolymer having one, some, or all of the following properties:
(i) a resin VR from greater than 1×10¹⁴Ω cm at 60° C. to less than 1×10¹⁶Ω cm at 60° C., or a resin VR from greater than 1×10¹⁴Ω cm at 60° C. to 1×10¹⁵Ω cm at 60° C.; and/or
(ii) a sheet VR from greater than 1×10¹⁴Ω cm at 23° C. to less than 1×10¹⁶Ω cm at 23° C., or a sheet VR from greater than 1×10¹⁴Ω cm at 23° C. to less than 7.0×10¹⁵Ω cm at 23° C.; and/or
(iii) a density from 0.860 g/cc to 0.890 g/cc, or from 0.860 g/cc to 0.880 g/cc, or from 0.865 g/cc to 0.875 g/cc; and/or
(iv) a melt index (12) from 10 g/10 min to 20 g/10 min, or from 10 g/10 min to 15 g/10 min, or from 11 g/10 min to 14 g/10 min; and/or
(v) a melting temperature, Tm, from 50° C. to 90° C., or from 50° C. to 80° C., or 55° C. to 75° C., or from 60° C. to 70° C.; and/or
(vi) a Vicat softening temperature from 30° C. to 50° ° C., or from 35° C. to 39° C. (hereafter Sheet1). Weight percent is based on total weight of the encapsulant sheet.

### 2. PV Module

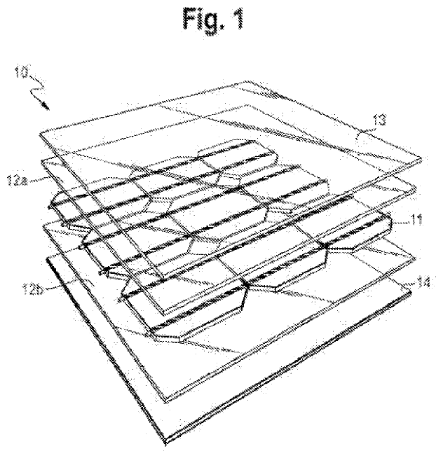

The present disclosure provides a photovoltaic (PV) module. A “photovoltaic cell”, “PV cell” and like terms refer to a structure that contains one or more photovoltaic effect materials of any of several inorganic or organic types. Nonlimiting examples of photovoltaic effect material include crystalline silicon, polycrystalline silicon, amorphous silicon, copper indium gallium (di)selenide (CIGS), copper indium selenide (CIS), cadmium telluride, gallium arsenide, dye-sensitized materials, and organic solar cell materials. As shown in FIG. 1, a PV module is typically employed in a laminate structure and has at least one light-reactive surface that converts the incident light into electric current, typically in outdoor applications. A PV cell may be flexible or rigid in nature and include the photovoltaic effect materials and any protective coating surface materials that are applied in their production as well as appropriate wiring and electronic driving circuitry.

“Photovoltaic module”, “PV module” and like terms refer to a structure including a PV cell. A PV module may also include a front cover sheet, front encapsulant sheet, rear encapsulant sheet, a backsheet, or a rear encapsulant sheet with the PV cell sandwiched between the front encapsulant sheet and rear encapsulant sheet.

The PV module includes (A) a front cover sheet, (B) a front encapsulant sheet, (C) a photovoltaic cell, (D) a rear encapsulant sheet; and (E) a rear cover sheet. FIG. 1 illustrates an exemplary PV module. The rigid PV module 10 includes a photovoltaic cell 11 (PV cell 11) surrounded or encapsulated by the front encapsulant sheet 12a and rear encapsulant sheet 12b. A front cover sheet 13 covers a front surface of the portion of the front encapsulant sheet 12a disposed over PV cell 11. A rear cover sheet 14 supports a rear surface of the portion of the rear encapsulant sheet 12b disposed on a rear surface of PV cell 11. Front cover sheet 13 and rear cover sheet 14 each is composed of glass, or acrylic resin, or polycarbonate. In an embodiment, front cover sheet 13 and rear cover sheet 14 each is composed of glass.

A portion of front encapsulant sheet 12a directly contacts PV cell 11 and another portion of front encapsulant sheet directly contacts rear encapsulant sheet 12b, as shown in FIG. 1. A portion of rear encapsulant sheet 12b also directly contacts a rear side of PV cell 11. In this way, front encapsulant sheet 12a and rear encapsulant sheet 12b fully encapsulate PV cell 11. As shown in FIG. 1, front encapsulant sheet 12a directly contacts the front cover sheet 13 and rear encapsulant sheet 12b directly contacts the rear cover sheet 14. The PV cell 11 is sandwiched between the front encapsulant sheet 12a and rear encapsulant sheet 12b such that the front encapsulant sheet 12a and rear encapsulant sheet 12b are both in direct contact with the PV cell 11. The front encapsulant sheet 12a and rear encapsulant sheet 12b are also in direct contact with each other in locations where there is no PV cell 11.

The encapsulant sheet of this disclosure can be the front encapsulant sheet, the rear encapsulant sheet, or both the front encapsulant sheet and rear encapsulant sheet. In an embodiment, the encapsulant sheet of this disclosure is the front encapsulant sheet. In another embodiment, the encapsulant sheet of this disclosure is both the front encapsulant sheet and the rear encapsulant sheet.

In an embodiment, the PV module includes a front encapsulant sheet 12a that is Sheet1 and a rear encapsulant sheet 12b that is Sheet1.

In an embodiment, the encapsulant sheet(s) of this disclosure are applied to an electronic device by one or more lamination techniques. Through lamination, the cover sheet is brought in direct contact with a first facial surface of the encapsulant sheet, and the electronic device is brought in direct contact with a second facial surface of the encapsulant sheet. The front cover sheet is brought into direct contact with a first facial surface of the front encapsulant sheet, the rear cover sheet is brought in direct contact with a second facial surface of the rear encapsulant sheet, and the electronic device(s) is secured between, and in direct contact with the second facial surface of the front encapsulant sheet and the first facial surface of the rear encapsulant sheet.

In an embodiment, the lamination temperature is sufficient to activate the organic peroxide and crosslink the material, that is, the curable material composed of the ethylene/C₄-C₈ α-olefin copolymer, the ion scavenger, organic peroxide, silane coupling agent, and co-agent (and optional additives). During crosslinking, the molecular chains of the ethylene/C₄-C₈ α-olefin copolymer couple by way of carbon-carbon bond. The silane coupling agent also interacts with the surface of the cover sheet to increase adhesion between the each encapsulant sheet its respective cover sheet. After lamination, the material is a reaction product of the ethylene/C₄-C₈ α-olefin copolymer, ion scavenger, the organic peroxide, the silane coupling agent, and the co-agent. The crosslinked encapsulant sheet is structurally and physically distinct to the crosslinkable material.

In an embodiment, the photovoltaic module includes:
(A) a front cover sheet;
(B) a front encapsulant sheet composed of
   (i) an ethylene/C₄-C₈ α-olefin copolymer having a resin volume resistivity (VR) from greater than 1×10¹⁴Ω cm at 60° C. to less than 1×10¹⁶Ω cm at 60 ° C.,
   (ii) from 0.01 wt % to 0.2 wt % of an ion scavenger,
(C) a photovoltaic cell;
(D) a rear encapsulant sheet composed of
   (i) an ethylene/C₄-C₈ α-olefin copolymer having a resin volume resistivity (VR) from greater than 1×10¹⁴Ω cm at 60° C. to less than 1×10¹⁶Ω cm at 60° C., or a resin VR from greater than 1×10¹⁴Ω cm at 60° C. to less than 1×10¹⁵ Ω cm at 60 ° C.; and/or
   (ii) from 0.01 wt % to 0.2 wt % of an ion scavenger;
(E) a rear cover sheet; and the photovoltaic module has a power loss after potential induced degradation (PID) test from 0.05% to less than 5.0%, or from 0.05% to less than 2%. In a further embodiment, the front encapsulant sheet and the rear encapsulant sheet each has a sheet VR from greater than 1×10¹⁴Ω cm at 23° C. to less than 1×10¹⁶Ω cm at 23 ° C., or a sheet VR from greater than 1×10¹⁴Ω cm at 23° C. to less than 7.0×10¹⁵Ω cm at 23° C.

In an embodiment, the photovoltaic module includes (A) a front cover sheet, (B) a front encapsulant sheet, (C) a photovoltaic cell, (D) a rear encapsulant sheet, and (E) a rear cover sheet. The front encapsulant sheet and the rear encapsulant sheet each is a crosslinked sheet and is composed of from 99.8 wt % to 99.98 wt % of an ethylene/C₄-C₈ α-olefin copolymer that is an ethylene/octene copolymer having (i) a resin VR from greater than 1×10¹⁴Ω cm at 60° C. to less than 1×10¹⁶ Ω cm at 60° C., or a resin VR from greater than 1×10¹⁴Ω cm at 60° C. to less than 1×10¹⁵ Ω cm at 60 ° C.; and/or (ii) a density from 0.860 g/cc to 0.880 g/cc; and/or (iii) a melt index (12) from 10 g/10 min to 15 g/10 min; and/or (iv) a melting temperature, Tm, from 50 ° C. to 80 ° C.; and/or (v) a Vicat softening temperature from 30 ° C. to 50° ° C.%; and the photovoltaic module has a power loss after potential induced degradation (PID) test from 0.05% to less than 1%. In a further embodiment, the front encapsulant sheet and the rear encapsulant sheet each has a sheet VR from greater than 1×10¹⁴Ω cm at 23° C. to less than 1×10¹⁶ Ω cm at 23° C., or a sheet VR from greater than 1×10¹⁴Ω cm at 23° C. to less than 7.0×10¹⁵Ω cm at 23° C.

By way of example, and not limitation, some embodiments of the present disclosure will now be described in detail in the following examples.

### EXAMPLES

Materials used in the inventive examples (IE) and comparative samples (CS) are set forth in Table 1 below.

TABLE 1

| Component | | |
|---|---|---|
| tradename | Composition and properties | Supplier |
| ENGAGE ™ | Ethylene/octene copolymer, resin VR: 2.86 × 10¹⁵ Ω · cm (@60° C.) | Dow |
| PV 8669 | d: 0.873 g/cc, I2: 14 g/10 min, Tm: 76° C., Vicat: 40° C. | |
| XUS 38679 | Ethylene/octene copolymer, resin VR: 2.74 × 0¹⁴ Ω · cm (@60° C.) | Dow |
| | d: 0.873 g/cc, I2: 13 g/10 min, Tm: 60° C., Vicat: 38° C. | |
| ENGAGE ™ | Ethylene/butene copolymer, resin VR: 8.97 × 10¹⁴ Ω · cm (@60° C.) | Dow |
| 8411 | d: 0.88 g/cc, I2: 18 g/10 min, Tm: 76° C., Vicat: 45° C. | |
| R04 | Ethylene/butene copolymer, resin VR: 2.68 × 10¹³ Ω · cm (@60° C.) | Dow |
| | d: 0.873 g/cc, I2: 14 g/10 min, Tm: 59° C., Vicat: 37° C. | |
| LUCENE ™ | Ethylene/butene copolymer, resin VR: 4.68 × 10¹⁴ Ω · cm (@60° C.) | LG |
| LC565 | d: 0.865g/cc, I2: 5 g/10 min, Tm: 36° C., Vicat: 35° C. | |
| IXE-100 | Ion scavenger | Toagosei |
| | Zr_{1-X}Hf_{X}Hₐ(PO₄)_{b}•mH₂O | Co. |
| IXEPLAS | Ion scavenger | Toagosei |
| | ZrₓAl_{1-X}Hₐ(PO₄)_{b}•mH₂O | Co. |
| EVAM 1SG038 | Ion scavneger masterbatch EVA MB with 4 wt % IXE-100 | Toyo Ink |
| POEM (prototype) | Ion scavenger masterbatch POE MB with 8 wt % IXE-100 | Toyo Ink |
| TBEC | Peroxide | Arkema |
| | tert-Butylperoxy 2-ethylhexyl carbonate [CAS: 34443-12-4] | |
| TAIC | Cross-linking agent | Farida |
| | triallyl isocyanurate | |
| VMMS | Silane coupling agent | Dow |
| | 3-(trimethoxysilyl)propylmethacrylate | |
| T770 | UV stabilizer | Alfa |
| | Decanedioic acid bis (2,2,6,6-tetramethyl-4-piperidyl) ester | Aesar |

### 1. Preparation of Encapsulant Sheet

Compounding of ion scavenger powders (IXE-100 and IXEPLAS) and resins. Resins were fed into Brabender mixer at set temperature (130° C.) and rotor speed of 10 rpm. Then the ion scavenger powders were weighed and added gradually into the Brabender mixer. The mixing was conducted at set temperature (130° C.) and rotor speed of 80 rpm for 5 minutes. The finished compound was collected and cut into small pieces. Those pieces were fed into the hopper of Brabender single-screw extruder and extruded into melt strand at 110° C. with screw speed of 25 rpm. The melt strand was fed into the Brabender pelletizer to produce ion scavenger powder master batch pellets. Then, the ion scavenger master batch samples were dry blended with polymer pellets with mixer with desired dosage.

For each composition, the polymer pellets (98.18 wt.%) were mixed with the cure package (1.00 wt. % peroxide, 0.50 wt. % crosslinking coagent, 0.25 wt. % silane coupling agent, and 0.07 wt. % UV stabilizer).

For each composition, after soaking at 40° C. for 4 hours, the pellets were fed into Labtech casting line with extruder temperature of 110° C. to avoid peroxide decomposition. Films with thickness of about 470 nm and width of 250 mm were fabricated.

These films (simulating front/rear encapsulant sheets) were used for the following module fabrication and performance tests.

Single Cell Module Lamination. The glass/glass bifacial modules used in this study were prepared with the following procedures.

The glass cover sheets in 4×6 square inches were cleaned using water and then dried before use. The encapsulant sheets were cut into pieces to fit the size of the glasses. Front glass cover sheet, front encapsulant sheet, photovoltaic cell, rear encapsulant film, and rear glass cover sheet were stacked together in the foregoing sequence. The lamination process was conducted on a PENERGY L036 laminator at 150° C. for 20 minutes, including 4 minutes vacuum process and 16 minutes pressing. The laminated samples were used for the PID stress test. Three identical single cell PV module samples were prepared for PID test to obtain the average value.

Properties of the front/rear encapsulant sheets are provided in Table 2 below.

TABLE 2

| | | | Power loss % | | | | | |
|---|---|---|---|---|---|---|---|---|
| | | Equivalent | after PID test | | | | | |
| | | IXE-100 | (96 h, −1500 V) | | Resin | Sheet | Sheet | |
| | | dosage | Front | Rear | VR @ | VR @ | VR @ | Transmittance % |
| | Samples | (wt %) | side | Side | 60° C. | 23° C. | 60° C. | (380-1100 nm) |
| CS-1 | ENGAGE PV 8669 | | −1.17% | −2.38% | 2.86E+15 | 3.61E+17 | 1.68E+16 | 91.79 |
| CS-1-1 | ENGAGE PV 8669 + 0.5 wt. % | 0.04 | 0.15% | −0.17% | | 1.73E+18 | 4.17E+16 | 91.55 |
| | POEM | | | | | | | |
| CS-1-2 | ENGAGE PV 8669 + 0.05% | | −1.53% | −5.93% | | 7.58E+16 | 1.38E+16 | 91.62 |
| | IXEPLAS | | | | | | | |
| CS-1-3 | ENGAGE PV 8669 + 0.2% | | −1.93% | −9.06% | | 5.36E+16 | 4.34E+15 | 91.12 |
| | IXEPLAS | | | | | | | |
| CS-2 | XUS 38679 | | −3.57% | −9.25% | 2.74E+14 | 4.77E+15 | 1.67E+15 | 91.94 |
| CS-2-1 | XUS 38679 + 0.0625 wt. % | 0.005 | −3.38% | −5.79% | | 7.32E+15 | 2.80E+15 | 91.56 |
| | POEM | | | | | | | |
| IE-2-2 | XUS 38679 + 0.25 wt. % POEM | 0.02 | −0.95% | −1.78% | | 6.21E+15 | 2.56E+15 | 91.6 |
| IE-2-3 | XUS 38679 + 0.5 wt. % POEM | 0.04 | −0.47% | −1.07% | | 5.05E+15 | 2.86E+15 | 91.43 |
| IE-2-4 | XUS 38679 + 0.04 wt. % IXE-100 | 0.04 | −0.24% | −0.88% | | 5.36E+15 | 2.43E+15 | 91.45 |
| IE-2-5 | XUS 38679 + 1 wt. % POEM | 0.08 | −0.98% | −1.92% | | 1.27E+16 | 5.34E+15 | 91.35 |
| IE-2-6 | XUS 38679 + 2.5 wt. % POEM | 0.2 | −0.08% | −1.22% | | 5.30E+16 | 6.90E+15 | 91.1 |
| CS-4 | ENGAGE 8411 | | −3.41% | −13.31% | 8.97E+13 | 1.03E+15 | 3.24E+14 | 91.72 |
| CS-4-1 | ENGAGE 8411 + 0.5 wt. % POEM | 0.04 | −3.13% | −11.98% | | 3.23E+15 | 5.01E+14 | 91.65 |
| CS-4-2 | ENGAGE 8411 + 1 wt. % POEM | 0.08 | −3.33% | −13.34% | | 5.63E+15 | 4.84E+14 | 91.5 |
| CS-5 | R04 | | −6.22% | −23.58% | 2.68E+13 | 1.14E+15 | 2.43E+14 | 91.73 |
| CS-5-1 | R04 + 0.04 wt. % IXE-100 | 0.04 | −6.85% | −26.06% | | 1.37E+15 | 1.08E+15 | 91.62 |
| CS-6 | LC565 | | −10.78% | −20.58% | 8.90E+13 | 2.87E+15 | 2.61E+14 | 91 |
| CS-6-1 | LC565 + 0.5% POEM | 0.04 | −6.89% | −14.87% | | 8.07E+15 | 3.82E+14 | 90.84 |

CS = comparative sample;
IE = inventive example

### Results

(A) XUS 38679 (CS-2) ethylene/octene copolymer has a resin VR 2.74×10¹⁴Ω cm at 60° C. and power loss of the PV module with CS-2 after PID test of −3.57%/−9.25% (front/rear). PV module with CS-2 front/rear encapsulant film has a power loss after potential induced degradation (PID) test of greater than 5% and therefore is not suitable as encapsulant sheet for a bifacial PV module. Encapsulant sheet composed of XUS 38679 ethylene/octene copolymer and 0.0625 wt % POEM (CS-2-1), exhibited a power loss after PID test of -3.38%/-5.79% (front/rear). With a power loss greater than 5%, CS-2-1 is not suitable as encapsulant sheet for bifacial PV module. Encapsulant sheet composed of XUS 38679 ethylene/octene copolymer and (i) 0.25 wt % POEM (IE-2-2), (ii) 0.5 wt. % POEM (0.04 wt. % IXE-100) (IE-2-3), (iii) 1 wt. % POEM (IE-2-5) and (iv) 2.5 wt. % POEM (IE-2-6), each exhibited a power loss after PID test of less than 2%, which is acceptable and is also lower than the power loss after PID test of -2.86% for CS-1, ENGAGE PV 8669.

(C) The power loss after PID test of ENGAGE 8411 (CS-4) is −3.41%/−13.31% (front/rear) and the power loss after PID test of R04 (CS-5) is −6.22%/−23.58% (front/rear). Consequently, ENGAGE 8411 and R04 are not suitable for bifacial PV module. Addition of 0.5 wt % POEM to ENGAGE 8411 (CS-4-1) or even 1.0 wt % POEM to ENGAGE 8411 (CS-4-2), show no improvement to power loss. The dosage was not further increased because no performance improvement trend and more dosage will impact the economics and film transparency.

Bounded by no particular theory, it is believed that VR represents ion mobility and concentration within the ethylene/C₄-C₈ α-olefin copolymer resin. The ion mobility and concentration in ethylene/C₄-C₈ α-olefin copolymer with resin VR less than 1×10¹⁴Ω cm at 60° C., such as R04 (CS-5) and ENGAGE 8411 (CS-4), is high, so the ion scavenger cannot neutralize all ions effectively. Consequently, the ion scavenger cannot prevent power loss effectively in ethylene/C₄-C₈ α-olefin copolymer with resin VR less than 1×10¹⁴Ω cm at 60° C.

It is specifically intended that the present disclosure not be limited to the embodiments and illustrations contained herein, but include modified forms of those embodiments including portions of the embodiments and combinations of elements of different embodiments as come within the scope of the following claims.

1. An encapsulant sheet comprising:
a material formed from
an ethylene/C₄-C₈ α-olefin copolymer having a resin volume resistivity (VR) from greater than 1×10¹⁴Ω cm at 60° C. to less than 1×10¹⁶Ω cm at 60° C.;
from 0.01 wt % to 0.2 wt % of an ion scavenger, and
the sheet has a transmittance greater than 91%.

2. The encapsulant sheet of claim 1 wherein the ethylene/C₄-C₈ a-olefin copolymer has a sheet VR from greater than 1×10¹⁴Ω cm at 23° C. to less than 1×10¹⁶Ω cm at 23° C.

3. The encapsulant sheet of claim 2 wherein the ethylene/C₄-C₈ a-olefin copolymer is an ethylene/octene copolymer having
(i) a resin VR from greater than 1×10¹⁴Ω cm at 60° C. to less than 1×10¹⁶Ω cm at 60° C.;
(ii) a density from 0.860 g/cc to 0.890 g/cc;
(iii) a melt index (12) from 10 g/10 min to 20 g/10 min;
(iv) a melting temperature, Tm, from 50° C. to 90° C.; and
(v) a Vicat softening temperature from 30° C. to 50° C.

4. The encapsulant sheet of claim 1 any of claims 1 3 wherein the ion scavenger is a zirconium phosphate.

5. The encapsulant sheet of claim 1 any of claims 1 4 wherein the material comprises a cure package comprising a peroxide, an optional curing agent, and an optional silane coupling agent.

6. The encapsulant sheet of claim 1 any of claims 1 5 comprising an additive selected from the group consisting of a UV stabilizer, an antioxidant, and combinations thereof.

7. A photovoltaic module comprising:
(A) a front cover sheet;
(B) a front encapsulant sheet composed of
(i) an ethylene/C₄-C₈ α-olefin copolymer having a resin volume resistivity (VR) from greater than 1×10¹⁴ Ω cm at 60° C. to less than 1×10¹⁶Ω cm at 60° C.,
(ii) from 0.01 wt % to 0.2 wt % of an ion scavenger,
(C) a photovoltaic cell;
(D) a rear encapsulant sheet composed of
(i) an ethylene/C₄-C₈ α-olefin copolymer having a resin volume resistivity (VR) from greater than 1×10¹⁴ Ω cm at 60° C. to less than 1×10¹⁶Ω cm at 60° C.,
(ii) from 0.01 wt % to 0.2 wt % of an ion scavenger;
(E) a rear cover sheet; and
the photovoltaic module has a power loss after potential induced degradation (PID) test from 0.05% to less than 5%.

8. The photovoltaic module of claim 7 wherein a portion of the front encapsulant sheet directly contacts the photovoltaic cell and a portion of the front encapsulant sheet directly contacts a portion of the rear encapsulant sheet.

9. The photovoltaic module of claim 8 wherein a portion of the rear encapsulant sheet directly contacts a portion of the photovoltaic cell.

10. The photovoltaic module of claim 7 wherein the front encapsulant sheet and the rear encapsulant sheet each is composed of an ethylene/C₄-C₈ α-olefin copolymer with a sheet VR from greater than 1×10¹⁴Ω cm at 23° C. to less than 1×10¹⁶ Ω cm at 23° C.

11. The photovoltaic module of claim 7 wherein the front encapsulant sheet and the rear encapsulant sheet each is a crosslinked sheet and is composed of
from 99.80 wt % to 99.98 wt % of an ethylene/C₄-C₈ α-olefin copolymer that is an ethylene/octene copolymer having
(i) a resin VR from greater than 1×10¹⁴Ω cm at 60° C. to less than 1×10¹⁶Ω cm at 60° C.;
(ii) a density from 0.860 g/cc to 0.890 g/cc;
(iii) a melt index (12) from 10 g/10 min to 20 g/10 min;
(iv) a melting temperature, Tm, from 50° C. to 90° C.; and
(v) a Vicat softening temperature from 30° C. to 50° C.; and
the photovoltaic module has a power loss after potential induced degradation (PID) test from 0.05% to less than 1%.
